(19) United States
(12) Patent Application Publication
(10) Pub. No.: US 2002/0080844 A1
(43) Pub. Date: Jun. 27, 2002

(54) (Ga,In)(N,As) laser structures using distributed feedback

(75) Inventors: Craig Tombling, Oxford (GB); Alistair Henderson Kean, Oxford (GB); Martin David Dawson, Glasgow (GB); Anthony Edward Kelly, Glasgow (GB)

Correspondence Address: LAHIVE & COCKFIELD, 28 STATE STREET, BOSTON, MA, 02109, US

(73) Assignee: KAMELIAN LIMITED, Oxford (GB)

(21) Appl. No.: 09/995,886

(22) Filed: Nov. 28, 2001

(30) Foreign Application Priority Data
Nov. 28, 2000 (GB) 0028950.4

(51) Int. Cl. H01S 3/08; H01S 5/00

(52) U.S. Cl. 372/96; 372/45

(57) ABSTRACT

A lasing structure comprises a distributed feedback grating associated with the active region, the grating defined by a periodic structure of quantum well intermixing. This quantum well intermixing (QWI) can be caused by focussed ion beam (FIB) implantation to the quantum well (QW) or multi-quantum well (MQW) active area. Subsequent annealing of the FIB damage will leave local periodic adjustments to the energy levels in the active region, providing the necessary DFB/DBR grating. Alternatively, or in addition, this periodic QWI structure or another periodic variation can be separated from the active region but associated therewith. For example, a QW or MQW structure which overlies the active region will carry the evanescent part of the waveform that is propagating in the active region. A periodic QWI structure in this region will thus affect the waveform. Other means by which this can be achieved are a periodic variation in the dopant concentration, for example created by FIB implantation or masked exposure to an ion beam or the like, a periodic variation in the material of the overlying layers, such as between semiconductor and insulator, and a periodic QWI structure in a QW or MQW structure overlying the active region.

### FIELD OF THE INVENTION

The present invention relates to GaInNAs laser structures using distributed feedback (DFB).

### BACKGROUND ART

DFB is a technique for tuning the output wavelength of a laser, for example in order to allow wavelength division multiplexing (WDM) of signals, but has yet to be applied commercially to novel GaInNAs laser structures. This is because DFB fabrication requires that a distributed Bragg grating (DBR) be formed on the part-formed epitaxial laser structure followed by further growth to complete the lasing structure. However, use of this approach for GaInNAs lasers involves the temporary exposure of aluminium-containing layers such as AlGaAs, which swiftly oxidise and hinder subsequent regrowth.

GaInNAs lasers are desirable for a number of reasons, including their ability to emit at longer wavelengths in the 1.3-1.6 μm range. Accordingly, novel methods are required for producing DFB structures which do not involve regrowth. The present invention is directed to this end, and provides means for doing so. Each operates on or through the overlying layers of the already formed laser structure and therefore overcome the above difficulties.

IEEE Journal of Selected Topics in Quantum Electronics, Vol. 4, No. 4, July/August 1998, p595 et seq, “Focused Ion-Beam Implantation Induced Thermal Quantum-Well Intermixing for Monolithic Optoelectronic Device Integration”, by Johann Reithmaier and Alfred Forchel, describes methods of forming a DFB laser using QWI to impart a periodicity to the laser structure. It describes the need to interrupt growth of the device in order to carry out FIB implantation and refers to the difficulty of regrowth over Al-containing layers due to the oxidation sensitivity of Al.

IEEE Photonics Technology Letters, Vol 7, No 8, August 1995, “Gain Coupled Distributed-Feedback GaInAs-GaAs Laser Structures Defined by Maskless Patterning with Focused Ion Beams” by Orth et al describes a laser structure in which Ga⁺ ions are implanted by focused ion beam (FIB) techniques in a periodic pattern, to create deliberate damage and locally reduce the carrier density and thus the optical gain. Thus, a periodicity is created in the optical gain. Orth et al emphasise that the energy of the implanted Ga⁻ ions is sufficient to reach the active region and thus the periodicity is not in a dopant element, nor is it in an area associated with but spaced from the active region. Further, Orth et al teach against thermal annealing and thus prevent intermixing.

JP-2083992 discloses a distributed feedback semiconductor laser in which Si is implanted by FIB techniques in a linear repetitive pattern. This step is carried out immediately after growth of the active layer, to ensure that the pattern is formed therein. Thus, the growth of the device must be interrupted and the periodicity is not in an area associated with but spaced from the active region.

### SUMMARY OF THE INVENTION

Accordingly, in its first aspect, the present invention provides a lasing structure comprising an active region providing gain and a distributed feedback grating in the same semiconductor layer structure, the distributed feedback grating being defined by a periodic variation associated with the active region but spaced therefrom.

Means by which this variation can be achieved include;

a periodic variation in the dopant concentration, for example created by FIB implantation or masked exposure to an ion beam or the like.

periodic variation in the material of the overlying layers, such as between semiconductor and insulator. This can be achieved in a variety of ways, but a particularly straightforward way is the conversion of an aluminium-containing alloy (such as one based on any of the AlAs, AlP, AlN etc systems) to contain Al₂O₃ such as by selective exposure to water vapour. The aluminium-containing alloy will generally need to contain a significant proportion of Al, ideally over 80%. This selective exposure can be provided by a mask or by vias.

periodic QWI in a QW or MQW structure overlying the active region.

The periodic structure of quantum well intermixing is an important and valuable approach. Accordingly, in its second aspect, the present invention provides a lasing structure comprising a distributed feedback grating associated with an active region of the (Ga,Al,In)(N,As) system, the grating being defined by a periodic structure of quantum well intermixing.

This quantum well intermixing (QWI) can be caused by focussed ion beam (FIB) implantation to the quantum well (QW) or multi-quantum well (MQW) active area. Subsequent annealing of the FIB damage will leave local periodic adjustments to the energy levels in the active region, providing the necessary DFB/DBR grating.

Alternatively, or in addition, the periodic QWI structure can be created in a QW or MQW structure separated from the active region but associated therewith. For example, a QW or MQW structure which overlies the active region will carry the evanescent part of the waveform that is propagating in the active region. A periodic QWI structure in this region will thus affect the waveform.

The present invention also relates to the methods by which laser structures can be created.

Accordingly, the present invention relates to a method of preparing a distributed feedback laser structure, comprising the steps of growing a laser structure and creating therein a periodic structure after completion of the lasing layers by implantation into those layers.

It also relates to a method of preparing a distributed feedback laser structure, comprising the steps of growing a layered laser structure and, after completion of the lasing layers, creating therein a periodic structure in at least one previously deposited layer by conversion of the material of that layer in a periodic pattern.

### BRIEF DESCRIPTION OF THE DRAWINGS

Embodiments of the present invention will now be described by way of example, with reference to the accompanying figures, in which;

FIGS. 1 to 3 are sections through a gain-coupled laser structure at an intermediate stage of production, FIG. 1 being a longitudinal section and

FIGS. 2 and 3 being vertical transverse sections on II-II and III-III respectively;

FIGS. 4 to 6 are like sections through the laser structure of FIGS. 1 to 3 after annealing;

FIGS. 7a and 7b are views of the spatial distribution of available quantum levels,

FIG. 7a corresponding to the pre-anneal structure of FIGS. 1 to 3 and

FIGS. 7a and 7b corresponding to different locations in the post-anneal structure of FIGS. 4 to 6;

FIGS. 8 to 10 show sections akin to those of FIGS. 1 to 3 but of a second embodiment, being an index coupled laser structure at an intermediate stage of production;

FIGS. 11 to 13 are like sections through the laser structure of FIGS. 8 to 10 after annealing;

FIGS. 14a and 14b are views of the spatial distribution of available quantum levels,

FIG. 14a corresponding to the pre-anneal structure of FIGS. 8 to 10 and

FIGS. 14a and 14b corresponding to different locations in the annealed structure of FIGS. 11 to 13;

FIGS. 15 to 17 show sections akin to those of FIGS. 1 to 3 but of a third embodiment, being a laser structure coupled by free carrier absorption;

FIG. 18 is a top view of a fourth embodiment, and

FIGS. 19 and 20 are sections akin to those of FIGS. 2 and 3 of the fourth embodiment, being a laser structure coupled by free carrier absorption;

FIG. 21 is a vertical longitudinal section of the fourth embodiment;

FIGS. 22 and 23 are like views of FIGS. 19 and 20, being sections on XXII and XXIII on FIG. 21;

FIG. 24 is a top view of a fifth embodiment, and

FIGs. 25 and 26 are sections akin to those of FIGS. 2 and 3 but of a fifth embodiment, being an index coupled laser structure, at an intermediate stage of production;

FIG. 27 is a horizontal section on XXVII showing the affected region of the fifth embodiment, after an oxidation step; and

FIGS. 28 and 29 are vertical sections on XXVII and XIX respectively through the device of the fifth embodiment, after oxidation.

### DETAILED DESCRIPTION OF THE EMBODIMENTS

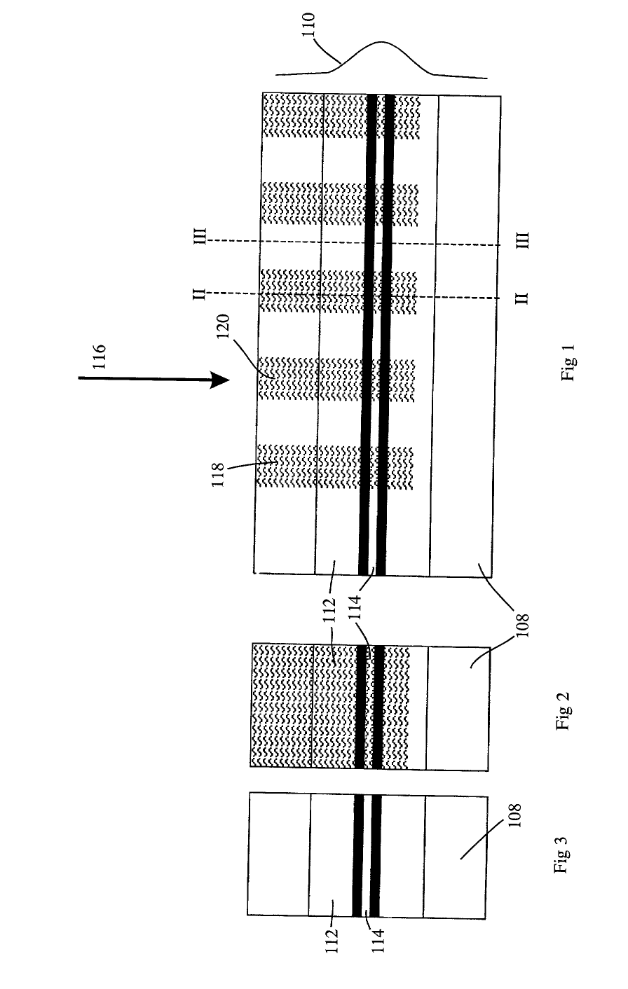

Referring to FIGS. 1 to 7, these show the production of a gain coupled (Ga,Al,In)(N,As) laser formed on a semiconductor substrate 108. The waveform 110 is confined in the active region 112 by a multi-quantum well (MQW) structure 114 in a known fashion. The active region is the area shown delineated above and below the MQW structure 114. In order to create a grating in the active region, it is necessary to form a periodic structure which will influence the waveform 110 as it propagates in the active region 112. According to the invention, a periodic structure is created in the active region 112 subsequent to its growth. In this first embodiment, a periodic structure is created by focussed ion beam (FIB) implantation 116 in selected areas 118, 120 etc shown in FIGS. 1 to 3 as shaded. FIB implantation is thus carried out in a periodic series of stripes across the active region 112 and which extend into the epitaxial layers grown on the substrate 108 sufficiently deeply to affect the active region 112 and MQW structure 114. This implantation causes damage to the semiconductor epitaxial material.

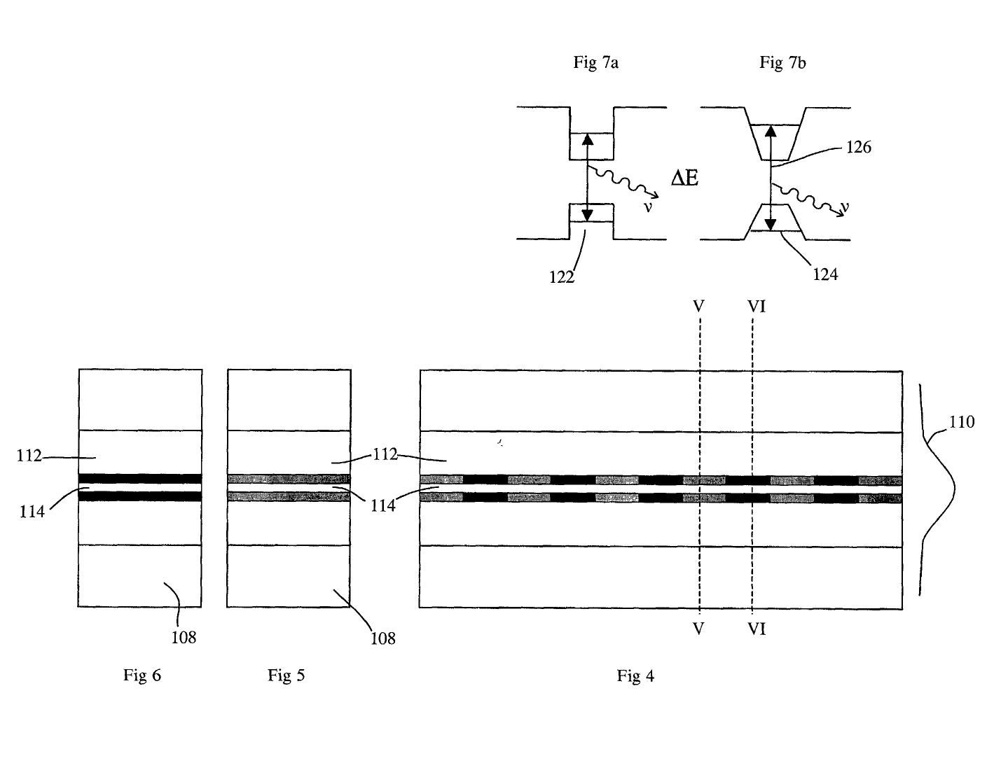

The structure is then annealed. This relaxes the damage caused to the substrate material, as shown in FIGS. 4 to 6. However, the MQW structure 114 is subjected to quantum well intermixing (QWI) through the annealing of this damage, and this locally affects the available quantum levels. FIGS. 7a and 7b show this illustratively; prior to FIB implantation and annealing, the structure (FIG. 7a) involves sharply defined quantum wells 122 whereas after annealing out the FIB damage the quantum wells 124 become less sharply defined and as a result the minimum energy gap increases slightly at 126.

The result of this is that the band gap of the material is adjusted where FIB implantation took place. Because the FIB implantation was periodic, the band gap and hence the gain in the active region now varies periodically. Accordingly, a grating is formed in the device which is able to be wavelength selective.

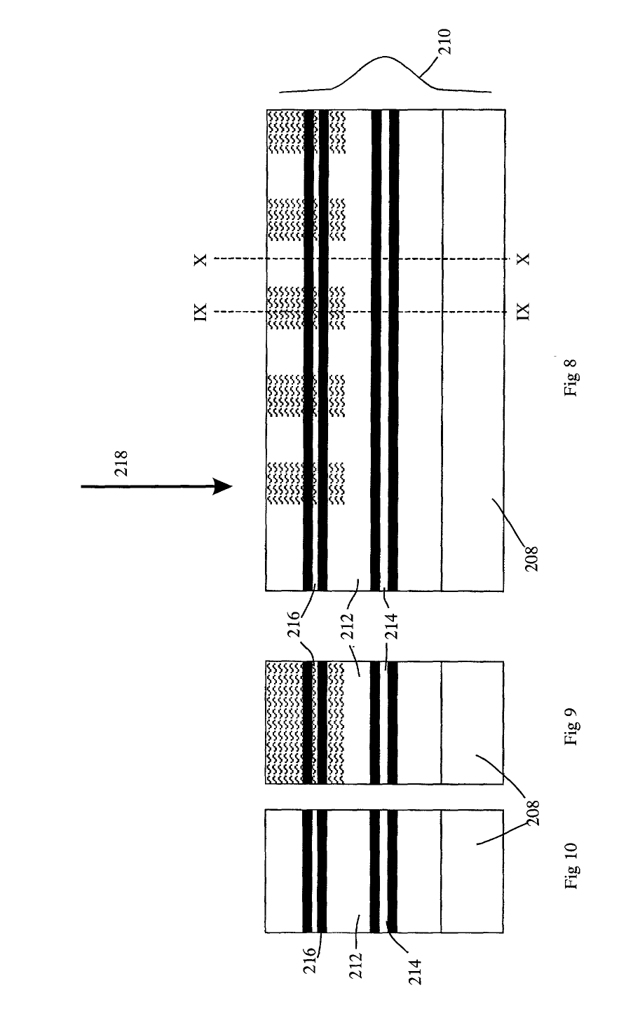

FIGS. 8 to 14 show a variation on the first embodiment. In this second embodiment, the laser structure comprises an active region 212 which (in this embodiment) comprises an MQW structure 214 to confine the waveform 210 as in the first embodiment. A second MQW structure 216 is formed in a semiconducting region above the active region 212, in the evanescent part of the waveform 210. The second MQW structure 216 can provide either an index change or an absorption change, and its preferred physical proximity to the centre of the active region 212 may vary accordingly.

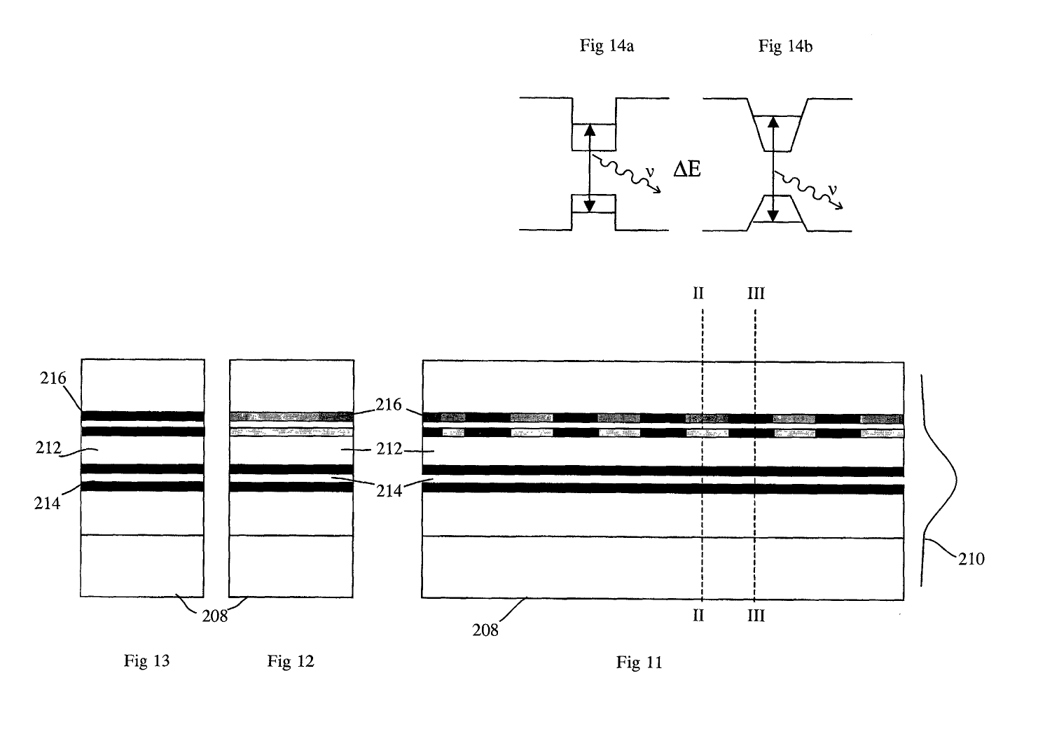

The structure is then subjected to FIB 218 as per the first embodiment. However, the energy of the ion beam is adjusted such that implantation damage does not reach the first MQW structure 214 but only the second MQW structure 216, above the first. Thus, when the structure is annealed as shown in FIGS. 11 to 13, a QWI pattern is produced but only in the second MQW structure 216. This again produces a periodic variation in band gap, and consequently the refractive index modulation, as shown in FIGS. 14a and 14b, FIG. 14a showing the pre-anneal energy levels of the second MQW structure, and FIG. 14b showing the post-anneal levels of the second MQW structure. Thus, the waveform 210 feels a periodic structure via its evanescent part interacting with the second MQW structure, whilst propagating in an MQW structure that does not have a varying gain and hence can be optimised to the required laser characteristic independent of the grating formed. The energy levels of the first and second quantum well layers may well be dissimilar. A structure can also be envisaged where the active region does not contain a MQW, with an MQW only provided in the cladding region with the purpose of providing index modulation.

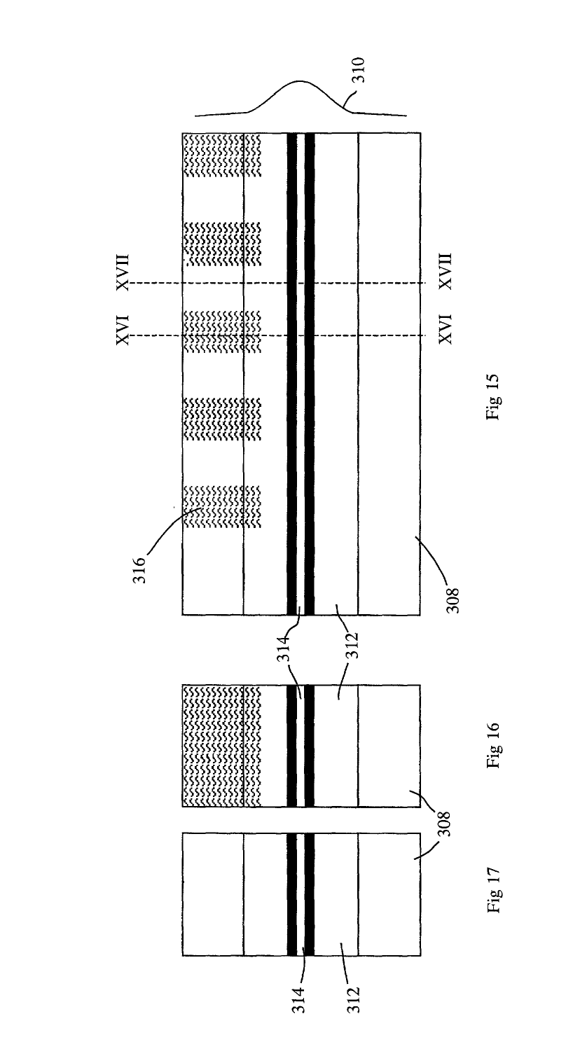

FIGS. 15 to 17 show a third embodiment of the present invention. Again, a substrate 308 with epitaxial layers grown on it has an MQW structure 314 which confines a waveform 310 in an active region 312. FIB implantation is employed to inject a suitable ion into regions 316 of the substrate above the MQW structure in which the evanescent part of the waveform 310 propagates. A range of ions and effects thereof are suitable. H⁺ ions will passivate existing dopants in that part of the substrate, or a new or additional dopant could be added to create a fresh doped area, reinforce an existing doping, or counteract an existing doping. The upper (Ga,Al,In)(N,As) epitaxial layers are is usually provided in a p⁺ form, and could thus be adjusted to p⁺⁺ or p⁻. Impurities could be deliberately added, thereby locally disturbing the e⁻-gas concentration. All of these will affect the optical absorption and refractive index of the material and hence affect the evanescent wave.

The FIB implantation is carried out in a periodic manner similar to the first and second embodiments. Thus, the effect on the waveform via its evanescent part is periodic and acts as a grating. As with the second embodiment, the principal MQW structure 314 is unaffected and can be optimised to the required gain characteristics.

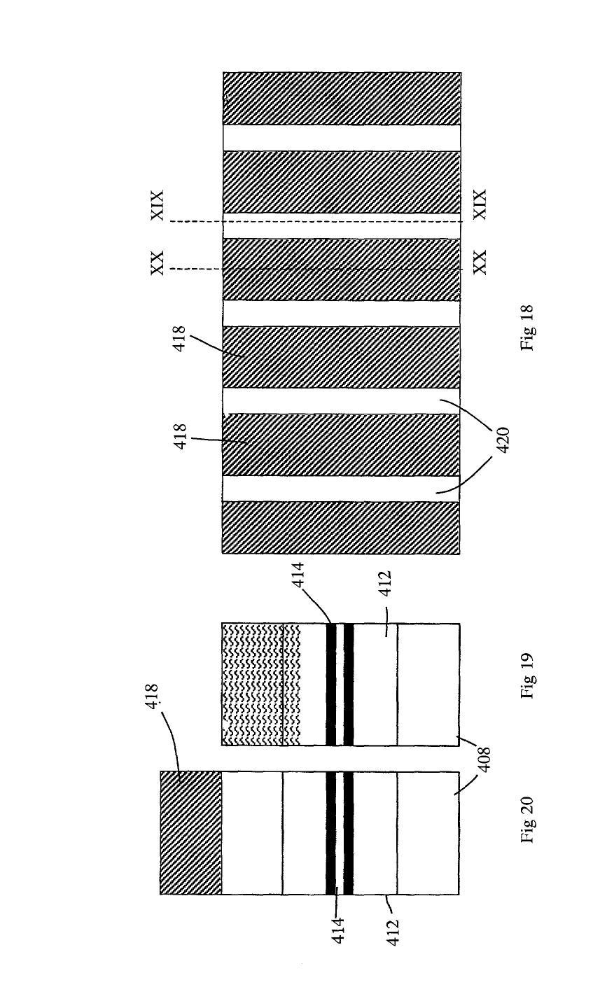

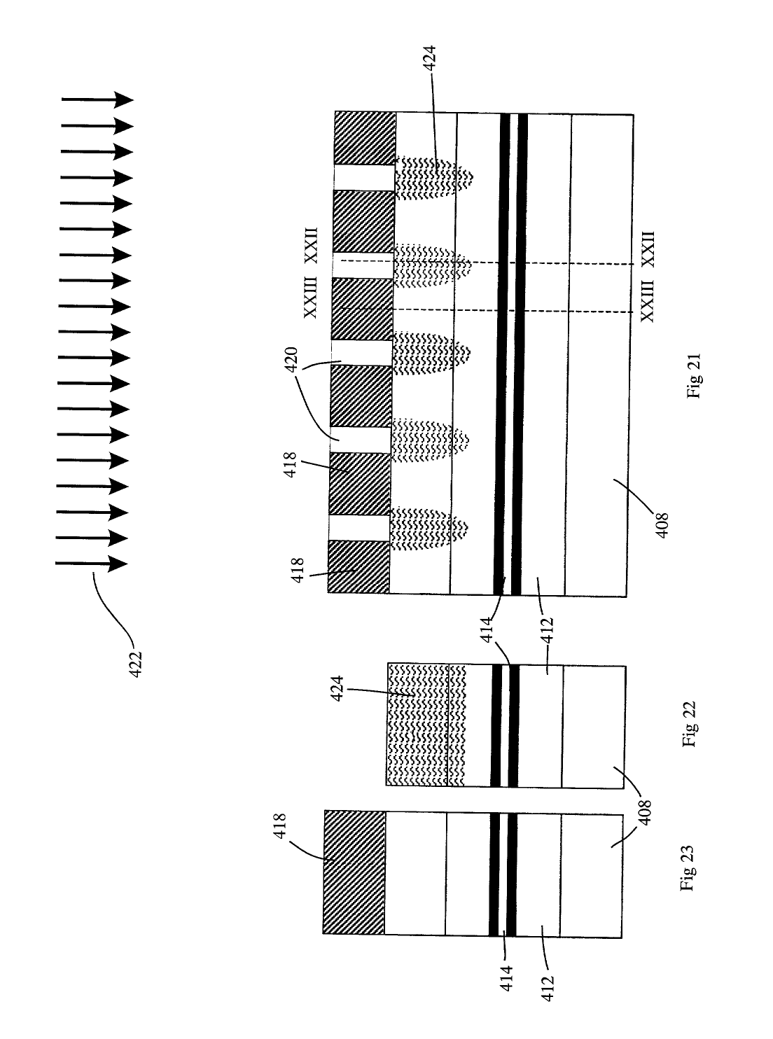

FIGS. 18 to 23 show an alternative way of producing the structure of the third embodiment where FIB implantation is not available. A periodic mask 418 is laid over the surface of the substrate 408. As previously, the substrate 408 contains an already formed laser structure of an active region 412 with MQW structure 414. The mask 418 contains openings 420 which are in the form of stripes transverse to the laser structure. A blanket ion beam 422 is then directed at the structure and is selectively absorbed by the mask 418. Where openings 420 are provided, the ion beam 422 impacts on the substrate 408 to form localised regions 424 of implantation. These act in like manner to the third embodiment above.

It can be difficult to provide a mask which is adequately deep to absorb an ion beam of sufficient energy, and which is also of a sufficiently fine resolution to form a first order grating. Typically a first order grating calls for a resolution of about 400 nm. Accordingly, where this arises, a second or higher order grating can be formed by adjusting the periodicity of the mask accordingly. A third order grating will call for a 1.2 μm grating period for devices operating around 1.55 μm. A higher order grating is usually undesirable owing to reduced side mode suppression, but such a structure might be used in the gain clamping of a semiconductor amplifier, where the lasing mode quality is of reduced consequence. Here the lasing action is present well away from the desired SOA gain window and acts to clamp the carrier density in the device.

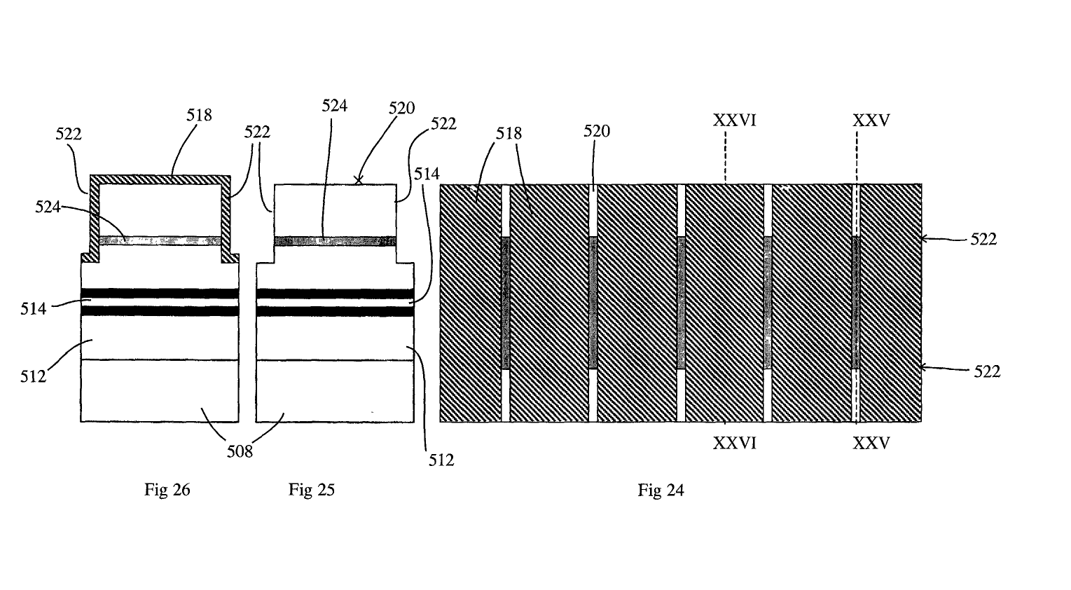

FIGS. 24 to 26 show the fifth embodiment at an intermediate stage of production. The substrate 508 with epitaxial layers grown upon it contains an active region 512 and an MQW structure 514 as before, but a step 522 is etched in the substrate above the MQW 514. This step runs longitudinally along the device on either side of the active strip. It is deep enough to have a noticeable extent but not sufficiently deep to meet the MQW structure 514. The step can be etched after growth, or developed by selective growth.

An aluminium-containing semiconductor layer 524 is previously formed in the substrate at a depth less that the step 522. Thus, the step 522 exposes edges of the layer 524. The layer can be of any suitable Al-containing alloy, such as one based on any of the (Ga,Al,In)((N,As), GaAs, AlAs, AlP, AlN etc systems. The preferred material is Al98GaO2As.

A mask 518 is then formed over the substrate 508 and over the step 522. The mask 518 is again periodic and includes openings 420 which are in the form of narrow stripes 520 transverse to the laser structure.

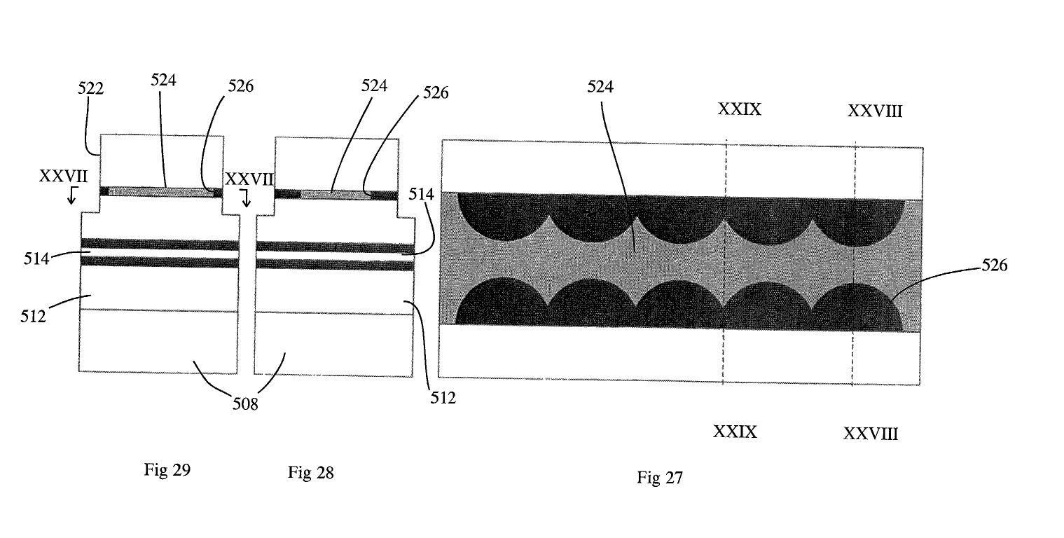

This device is then exposed to a oxidising atmosphere, such as water vapour (H₂O_{(g)}). The Al-containing layer 524 is oxidised inward from the exposed areas beneath the stripes 520. Since the stripes are narrow, they act as point sources of oxidation for the layer 524 and oxidation may take the form of a semicircular front526 extending inwards from the intersection of the stripe 520 and the layer 524. The oxidation time can be controlled such that (for example) the semicircular fronts of adjacent stripes 520 just meet. The mask 518 can then be removed. In this case, the resulting structure will be as shown in FIGS. 27 to 29, with the width of the remaining Al-containing semiconductor layer 524 being modulated with a periodic pattern. The oxidised parts will contain insulating Al₂O₃ and hence not contribute to conduction processes in the device. This periodic structure provides a very large index modulation and is again felt by the evanescent part of the waveform and is sufficient to establish a grating.

Thus, the present invention provides various means by which a DFB/DBR structure can be created in a semiconductor laser without needing to interrupt growth of the laser structure. In all of the above embodiments, offered by way of example, the DFB/DBR structure is created by manipulation of the device structure after growth of the laser structure. It will be appreciated that many variations may be made to the above-described embodiments without departing from the scope of the present invention.

1. A lasing structure comprising an active region providing gain and a distributed feedback grating in the same semiconductor layer structure,
the distributed feedback grating being defined by a periodic variation associated with the active region but spaced therefrom through being located in an overlying layer.

2. A lasing structure according to claim 1 in which the variation is in a dopant concentration.

3. A lasing structure according to claim 2 in which the variation in the dopant concentration is created by one of focussed ion beam implantation and masked exposure to an ion beam.

4. A lasing structure according to claim 1 in which the periodic variation is a variation in the material of the overlying layers.

5. A lasing structure according to claim 4 in which the material of the overlying layers varies periodically between semiconductor and insulator.

6. A lasing structure according to claim 5 in which the material varies between aluminium-containing alloy and Al₂O₃.

7. A lasing structure according to claim 6 in which the aluminium-containing alloy is one based on the (Ga,Al,In)(N,As) system.

8. A lasing structure according to claim 6 in which the Al₂O₃ is derived from oxidation of an aluminium-containing alloy.

9. A lasing structure according to claim 8 in which the aluminium-containing alloy from which the Al₂O₃ is derived is one of GaAlAs, AlAs, AlP and AlN.

10. A lasing structure according to claim 6 in which the respective aluminium-containing alloy contains a proportion of Al over 80%.

11. A lasing structure according to claim 1 in which the periodic variation is a periodically repeating pattern of quantum well intermixing.

12. A lasing structure comprising a distributed feedback grating associated with an active region of the (Ga,In)(N,As) system, the grating being defined by a periodic structure of quantum well intermixing.

13. A lasing structure according to claim 12 in which the quantum well intermixing is caused by focussed ion beam implantation to a quantum well or multi-quantum well.

14. A lasing structure according to claim 13 in which the structure is annealed.

15. A lasing structure according to claim 12 in which the periodic structure is associated with a quantum well structure separated from the active region but associated therewith.

16. A lasing structure according to claim 15 in which the periodic structure is formed in a quantum well structure which overlies the active region.

17. A lasing structure comprising an active region providing gain and a distributed feedback grating in the same semiconductor layer structure, the distributed feedback grating being defined by a periodic variation in which the material of the relevant layer varies between semiconductor and insulator, the variation occurring in a layer associated with the active region but spaced therefrom.

18. A lasing structure according to claim 17 in which the periodic variation is present in the material of the layers overlying the active region.

19. A lasing structure according to claim 1 7 in which the material varies between aluminium-containing alloy and Al₂O₃

20. A lasing structure according to claim 19 in which the aluminium-containing alloy is one based on the (Ga,Al,In)(N,As) system.

21. A lasing structure according to claim 19 in which the Al₂O₃ is derived from oxidation of an aluminium-containing alloy.

22. A lasing structure according to claim 21 in which the aluminium-containing alloy from which the Al₂O₃ is derived is one of GaAlAs, AlAs, AlP and AlN.

23. A lasing structure according to claim 19 in which the respective aluminium-containing alloy contains a proportion of Al over 80%.

24. A method of preparing a distributed feedback laser structure, comprising the steps of growing a laser structure and creating therein a periodic structure after completion of the lasing layers by implantation into those layers.

25. A method according to claim 24 in which the implantation step is by way of focussed ion beam implantation.

26. A method according to claim 24 in which the periodic structure is a periodically repeating pattern of quantum well intermixing.

27. A method according to claim 24 in which the periodic structure is a periodically repeating pattern of dopant content.

28. A method according to claim 24 in which the periodic structure is spaced from the lasing layers but associated therewith.

29. A method of preparing a distributed feedback laser structure, comprising the steps of growing a layered laser structure and, after completion of the lasing layers, creating therein a periodic structure in at least one previously deposited layer by conversion of the material of that layer in a periodic pattern.

30. A method according to claim 29 in which the material varies between aluminium-containing alloy and Al₂O_{3.}

31. A method according to claim 30 in which the aluminium-containing alloy is one based on the (Ga,Al,In)(N,As) system.

32. A method according to claim 30 in which the Al₂O₃ is derived from oxidation of an aluminium-containing alloy.

33. A method according to claim 32 in which the aluminium-containing alloy from which the Al₂O₃ is derived is one of GaALAs, AlAs, AlP and AlN.

34. A method according to claim 30 in which the respective aluminium-containing alloy contains a proportion of Al over 80%.
